(19) United States
(12) Patent Application Publication
(10) Pub. No.: US 2024/0420003 A1
(43) Pub. Date: Dec. 19, 2024

(54) TAPERED NANOWIRE DEVICE FOR QUANTUM COMPUTING

(71) Applicant: YEDA RESEARCH AND DEVELOPMENT CO. LTD., Rehovot (IL)

(72) Inventor: Haim BEIDENKOPF, Rehovot (IL)

(73) Assignee: YEDA RESEARCH AND DEVELOPMENT CO. LTD., Rehovot (IL)

(21) Appl. No.: 18/699,893

(22) PCT Filed: Nov. 7, 2022
(86) PCT No.: PCT/IL2022/051178

§ 371 Date: Apr. 10, 2024

Related U.S. Application Data
(60) Provisional application No. 63/276,623, filed on Nov. 7, 2021.

(51) Int. Cl. G06N 10/40

(52) U.S. Cl. CPC G06N 10/40

(57) ABSTRACT

The present invention relates to a quantum computing device based on manipulating Majorana Zero Mode excitations (MZMs) in topological superconducting regions formed in a tapered nanowire or similar structure. The tapering of the NW structure results in the formation of discrete regions of topological superconductivity having MZMs at their end boundaries, and thereby facilitates establishing the MZMs without delicate tuning procedures. A quantum swap gate is provided, utilizing two such structures in contact and disposed orthogonally to one another. Applying a magnetic field selectively lengthens the region of one structure while shortening the region of the other, allowing voltage and magnetic field changes to manipulate and interchange the MZM quantum states of the two structures to effect the swap operation.

### FIELD OF THE INVENTION

The present invention relates to the field of quantum computing, and, in particular, to the use of superconducting nanostructures for handling quantum information.

### BACKGROUND OF THE INVENTION

Nanowires (NWs) and nanotubes approximating 1-dimensional structures are a basis for topological superconducting devices, in which Majorana Zero Modes (MZM) are formed at the boundaries of topological superconducting regions. MZMs are zero-energy quasiparticle excitations which are electrically neutral, which are their own anti-particles, and which exhibit non-Abelian exchange statistics. These properties make MZMs desirable for use in quantum computing, by occupying degenerate zero-energy ground states in which quantum qubits may be encoded.

MZMs possess several advantages in a quantum computing environment, including immunity to decoherence and a high degree of noise-resistance, which would greatly reduce or altogether eliminate the need for large-scale redundancies and burdensome fault-tolerance measures.

Establishing a regime of topological superconductivity in such a 1-dimensional structure, however, requires careful tuning of the chemical potential of the structure. This is typically performed using external gating, which typically depends on a delicate balance of external parameters. It would therefore be highly beneficial and desirable to have microfilament devices which are not restricted by such tuning requirements. This goal is met by embodiments of the present invention.

### SUMMARY OF THE INVENTION

Embodiments of the present invention provide 1-dimensional nanostructures which facilitate establishing regions of 1-dimensional topological superconductivity without the need for elaborate tuning procedures. Certain embodiments also provide a novel mechanism for transporting MZMs from one location to another location. Further embodiments provide a swap gate for interchanging the respective quantum states of MZMs in two different locations.

In one embodiment this invention provides a quantum computing device comprising:
a substrate;
a tapered nanowire (NW) disposed on the substrate;
a superconducting layer in quantum proximity with the tapered nanowire; and
a voltage source;
wherein the voltage source is connected to the tapered NW and configured to produce and manipulate at least one discrete superconducting region within the tapered NW.

In one embodiment of the quantum computing device Majorana Zero Modes (MZMs) are present at the boundaries the at least one discrete superconducting region. In one embodiment of the quantum computing device the tapered NW comprises a semiconducting material. In one embodiment of the quantum computing device the semiconducting material is a high spin-orbit coupling material. In one embodiment of the quantum computing device the high spin-orbit coupling material is selected from Indium Arsenide (InAs) or Indium Antimonide (InSb). In one embodiment of the quantum computing device the tapered NW is gate-defined. In one embodiment of the quantum computing device the substrate is conductive. In one embodiment of the quantum computing device the substrate is doped silicon. In one embodiment the doped silicon is highly doped. In another embodiment the doped silicon is either n-type or p-type. In one embodiment the quantum computing device further comprises at least one insulating layer disposed in between the substrate and the tapered NW. In another embodiment, the device comprises additional layers to improve coupling between layers. In one embodiment of the quantum computing device the superconducting layer comprises at least one superconducting metal. In one embodiment of the quantum computing device the superconducting layer at least partially covers the tapered NW. In one embodiment the quantum computing device further comprises at least one gate, configured to control the electric potential within the tapered NW. In one embodiment the at least one gate is a back gate. In another embodiment, gate-defined NWs are coupled to a 2D electron gas.

In one embodiment the presently disclosed subject matter provides a crossed tapered NW device, the device comprising:
a substrate;
a first tapered NW and a second tapered NW, wherein the orientation of the first tapered NW is substantially orthogonal to the orientation of the second tapered NW;
at least one voltage source;
wherein the at least one voltage source is configured to produce and manipulate at least one discrete superconducting region within each of the first tapered NW and the second tapered NW; and
a magnet having an adjustable orientation for establishing a magnetic field at a selected orientation to change the length of the at least one superconducting region within each of the first tapered NW and the second tapered NW.

In one embodiment of the crossed tapered NW device the first tapered NW and the second tapered NW comprise a semiconducting high spin-orbit coupling material. In one embodiment the first tapered NW and the second tapered NW are gate-defined NWs. In one embodiment the crossed tapered NW further comprises electrodes disposed at the ends of the first tapered NW and the second tapered NW and wherein the at least one voltage source is configured to apply a potential across each of the first tapered NW and the second tapered NW. In one embodiment the crossed tapered NW further comprises at least one gate configured to control the electric potential within the first tapered NW and the second tapered NW. In one embodiment the crossed tapered NW is provided for use in a quantum computer.

In one embodiment the presently disclosed subject matter provides a method of performing a quantum computing swap function, the method comprising:
providing the crossed tapered NW device, as disclosed herein;
adjusting the voltage of the first tapered NW and second tapered NW to zero volts with respect to the substrate;
adjusting the selected orientation of the magnetic field to increase the length of the superconducting region in the first tapered NW and decrease the length of the superconducting region in the second tapered NW;
increasing the voltage of the first tapered NW and second tapered NW to a first positive voltage with respect to the substrate;
increasing the voltage of the first tapered NW and second tapered NW to a second positive voltage with respect to the electrode, wherein the second positive voltage is greater than the first positive voltage;
adjusting the selected orientation of the magnetic field to increase the length of the superconducting region in the second tapered NW and decrease the length of the superconducting region in the first tapered NW; and
reducing the voltage of the first tapered NW and second tapered NW to zero volts with respect to the substrate.

### BRIEF DESCRIPTION OF THE DRAWINGS

The subject matter disclosed may best be understood by reference to the following detailed description when read with the accompanying drawings in which:

FIG. 1 shows kinked InAs nanowires (NWs). As-grown kinked InAs NWs emerging from an InAs (001) faceted surface. (FIGS. 1A and 1B) Their irregular and elongated shape is clear from the scanning electron microscope (SEM) images. FIG. 1C shows the shape of the kinking NW modeled by Monte Carlo simulations. FIG. 1D shows a schematic illustration of the nanoflag NW.

FIG. 2 shows a twin plane in tapered NWs. FIG. 2A shows a TEM image showing the tip of a kinked NW with a zinc-blende (ZB) structure and occasional diagonal double twin planes. FIG. 2B shows a high-resolution TEM image showing more clearly a couple of diagonal double twin planes. Schematic illustrations of (FIG. 2C) a single and (FIG. 2D) a double twin plane are shown.

FIG. 3 shows the density-of-state response to tapering. FIG. 3A shows a topographic STM image of a segment of a tapered NW. FIG. 3B shows dI/dV measured along a line displaying the spectrum evolution. FIG. 3C shows a modeled segment of a NW based on the topography FIG. 3A. FIG. 3D shows a Kwant simulation of local density of states within the tapered NW in FIG. 3C. The white line in FIG. 3B and the dotted line in FIG. 3D are guides to the eye.

FIG. 4 shows the surface superlattice potential. FIG. 4A shows a representative STM topography of the atomic arrangement of the (110) surface showing 4 unit cell chains arranged in rows. FIG. 4B shows initial As adatom placement a non-(110) InAs surface (In ions are not visible). FIG. 4C shows As adatom reconstruction into the superstructure following a minimization procedure within the LAMMPS molecular dynamics simulator Tersoff potential transforms.

FIG. 5 shows approaches to tuning Kramer's degeneracy to the chemical potential and to manipulating Majorana modes. FIG. 5A shows how typically the chemical potential is tuned by capacitive gating. FIG. 5B shows how the periodic atomic-scale potential will fold the quantized band structure, inducing additional Kramer's degeneracies at the edges of the folded Brillouin zone that can be tuned to the chemical potential by engineering the periodic potential. FIG. 5C shows how tapered NWs, where the diameter varies along the NW, will vary the sub-band energy gaps with pushing Kramer's degeneracies across the chemical potential. FIG. 5D shows the Van Hove singularities seen in the Kwant simulation (false color) of the tapered NW (top panel) follow a naïve quantum particle in a box calculation (dotted line); inducing superconductivity (yellow shaded) at a certain chemical potential (dashed line) will give rise to topological superconducting segments. Tuning the chemical potential by the gate will transport the topological segments in the tapered NW (arrows).

FIG. 6 conceptually illustrates a tapered NW device for quantum computing, according to an embodiment of the present invention.

FIG. 7 conceptually illustrates a cross-section of a tapered NW, according to another embodiment of the present invention, showing regions of topological superconductivity and the corresponding Majorana Zero Modes (MZMs) on the regions' boundaries.

FIG. 8 illustrates cross-sections of two tapered NWs in an orthogonal configuration with an applied external magnetic field, as employed in a device for use in quantum computing according to a further embodiment of the present invention.

FIG. 9 illustrates the orthogonal two-tapered NW device configuration of FIG. 8, conceptually showing respective regions of topological superconducting and their corresponding Majorana Zero Modes, according to the embodiment of the present invention.

FIG. 10A conceptually illustrates the NW device configuration, tuning voltage and magnetic field setting of FIG. 9 at the start of an operational sequence of a swap gate for use in quantum computing.

FIG. 10B conceptually illustrates the NW device configuration, tuning voltage and magnetic field setting of FIG. 9 for a first step of the operational sequence of the swap gate.

FIG. 10C conceptually illustrates the NW device configuration, tuning voltage and magnetic field setting of FIG. 9 for a second step of the operational sequence of the swap gate.

FIG. 10D conceptually illustrates the NW device configuration, tuning voltage and magnetic field setting of FIG. 9 for a third step of the operational sequence of the swap gate.

FIG. 10E conceptually illustrates the NW device configuration, tuning voltage and magnetic field setting of FIG. 9 for a fourth and final step of the operational sequence of the swap gate.

FIG. 11 shows a birds eye view SEM image of low-density InAs nanoflags. The arrows indicate the edge steps of nanoflag side as compared to the flat 110 surface of the nanoflag seen in the center of the image. The inset shows a low-magnification TEM image of stem (wurtzite, WZ) and kinked and tapered nanoflag (zinc-blende, ZB).

FIG. 12A shows a top-view SEM image of an InAs nanoflags sample. Kinked tips point out in particular directions perpendicular to the symmetric lines seen clearly in the relative Fast Fourier Transform (FFT) image (inset). FIG. 12B shows a larger magnification SEM image showing that occasionally, two kinked NWs form intersections. The crossed portion of the tapered NWs is shown and indicated with an arrow wherein two superconducting regions (shown as superimposed greyed rectangles) cross.

FIG. 13A shows a TEM image of the kink of the NW showing the change from WZ to ZB structure and FIG. 13B shows very unique and double twin planes which result from two subsequent rotations of the lattice.

FIG. 14 shows two spectroscopic linecuts taken at slightly distant locations across the tapered NW show similar gross features. The top linecut is cropped from the full linecut shown in FIG. 3. The bottom one was taken about 5 nm below it over the same distance of 100 nm. Their similarity signifies that the dispersing features result from the overall confinement while local disorder changes only fine details.

FIG. 15 shows a NW profile extracted from Kwant simulation by following the sharp peaks in the spatial derivative of the NW's topographic image. 100 nm of straight segments of matching width where padded on the two ends to remove artifacts of finite length quantization.

FIG. 16 shows a schematic two crossed tapered NWs of FIG. 8 further comprising conducting pads at each end of the tapered NWs, together with a back-gate, in a device configuration.

For simplicity and clarity of illustration, elements shown in the figures are not drawn to scale, and some dimensions are exaggerated to visually emphasize essential features. In particular, NWs and their cross-sections are shown with an exaggerated taper for clarity. In some places, reference numerals are repeated among the figures to indicate corresponding or analogous features.

### DETAILED DESCRIPTION OF THE PRESENT INVENTION

A goal of the presently disclosed subject matter is to provide a geometry which facilitates the manipulation of Majorana Zero Modes (MZMs). In one embodiment, a tapered nanowire (NW) defines a region wherein topological superconducting regions are present. The tapered structure of the NW facilitates discrete topological superconducting regions. In a case where the NW is not tapered the whole of the NW can be either fully topologically superconducting or non-topologically superconducting. To this end, tapering of NWs can be carried out in many different ways, as disclosed herein. For example, 3-dimensional NWs on surfaces or 2-dimensional gate-defined NWs.

Topological superconductors are a class of superconducting materials characterized by sub-gap zero energy modes, known as MZM (also known as Majorana bound states, or Majoranas).

The term “nanowire” (NW) herein denotes a microscopic structure capable of supporting non-localized topologically 1-dimensional quantum-mechanical properties. The “nano” prefix indicates that the structure has a very small diameter (generally in the order of nanometers), but there are no explicit constraints regarding the overall length of the structure; the structure's length, however, is understood to be many times larger than its diameter. Additional qualifications and descriptions herein further define this term in the context and practice of the present invention.

In one embodiment, the term “tapered NW” herein denotes a NW characterized as geometrically approximating a truncated cone (or “frustum”) having a major (larger area) base and a minor (smaller area) base with respective diameters which are both much smaller than the NW height (or its length, when it is oriented horizontally). As will become clear, the tapering of a NW is not restricted to a 3D frustrum shape, but can also be any shape that is tapered, even in two dimensions. In one embodiment, the tapered NW is flat. In another embodiment the tapered NW is a flat, gate-defined NW. In another embodiment, the tapered NW is gate-defined. Typically, gate-defined wires are produced on substrates and are coupled to 2D electron gases. The orientation of a NW is thus taken to be the orientation of its longitudinal 1-dimensional axis, where the direction of orientation is taken to be the direction from the major base to the minor base. A typical height of a tapered NW (or its length, when it is oriented horizontally) is measured in microns, and typical diameters measure in the range of 50 nm to 100 nm, wherein the minor base diameter is on the order of nanometers to tens of nanometers smaller than the major base diameter. In some embodiments, the terms “nanowire”, “NW”, “nanofilament”, “tapered nanofilament”, “tapered NW” and “nanostructure” are used interchangeably.

In one embodiment, the tapered NW comprises a semiconductor. In one embodiment, the NW consists of a semiconductor. In one embodiment the tapered NW is semiconducting. In one embodiment, the tapered NW comprises a semiconductor with high spin-orbit coupling. In quantum mechanics “spin-orbit coupling” refers to a relativistic interaction between a particle's spin with its motion inside a potential. Non-limiting examples of semiconductors of high spin-orbit coupling include: Indium Arsenide (InAs) and Indium Antimonide (InSb). Other non-limiting examples of NWs include: NWs of metal, semiconductor, or inorganic molecules; and carbon nanotubes. Fabrication and manipulation of tapered NWs are currently available using known techniques. In one embodiment the tapered NW comprises transition-metal dichalcogenides (TMDs). In one embodiment the tapered NW consists of TMDs. In one embodiment the TMD is selected from a group comprising: MoS₂, WS₂, MoSe₂, WSe₂, MoTe₂ or combinations thereof.

Although examples are shown herein of particular fabricated tapered nanostructures, a principal feature of the presently disclosed subject matter is not bound to the particular structures that are described herein. In one embodiment, the presently disclosed subject matter relates to a tapered NW structure that facilitates the presence of discrete topological superconducting regions with corresponding MZMs. In one embodiment, the tapered NW is a structure that is fabricated on a substrate, as described herein. In another embodiment, the tapered NW structure is a gate-defined tapered nanostructure comprised within a semiconducting material. In one embodiment the terms “semiconductor”, “semiconducting material”, “semiconducting medium” are used interchangeably. In one embodiment, manipulation of Majoranas is facilitated by the tapered NW structure.

In some embodiments the tapered NWs are gate-defined. As used herein “gate-defined” NWs refer to NWs that are produced in a material by means of at least one gate electrode. The use of gate-defined NWs can be extrapolated to any desired shape and device structure, according to the requirements of a particular device optimized to achieve the required topological superconductivity, in two or three spatial dimensions. Typically, gate-defined NWs require coupling to a 2D electron gas (2DEG) on a substrate. In some embodiments a plurality of gate electrodes are used to achieve at least one gate-defined tapered NW. In some embodiments, the gate can be a top, bottom and/or side-gates, used independently or in any combination, to achieve the desired gate-field and/or gate-profile to produce the desired shape of the resulting NW. Gate-defined structures are well known to experts in the art. Thus, all the components required to enable the implementation of gate-defined structures defined herein are considered to be within the scope of the presently disclosed subject matter.

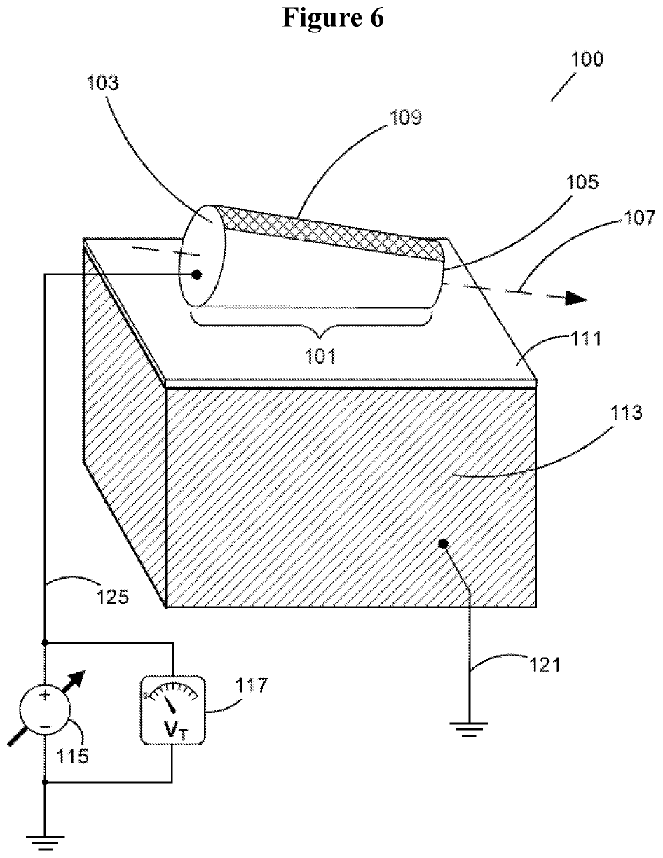

FIG. 6 conceptually illustrates a tapered NW device 100 according to an embodiment of the present invention. A tapered NW 101 (with a major base 103 and a minor base 105 so that the tapered NW 101 has an orientation 107) is in contact or quantum proximity with a superconducting layer 109, which partially, but not completely, covers tapered NW 101. As used herein “quantum proximity” denotes a close relative positioning of two structures, such that a physical property or state of one structure is capable of detectably affecting a quantum-mechanical property or state of the other structure. In one embodiment, the superconducting layer 109 completely covers the top of the NW 101. In one embodiment the superconducting layer 109 partially covers the top of the NW 101. In a related embodiment, tapered NW 101 is constructed of a semiconductor material, a non-limiting example of which is Indium Antimonide (InSb) or Indium Arsenide (InAs). In another related embodiment, superconducting layer 109 is a superconducting metal, non-limiting examples of which include Aluminum and Niobium. In another related embodiment, superconducting layer 109 comprises a superconducting element. In another related embodiment, superconducting layer 109 comprises a superconducting compound. In another related embodiment, superconducting layer 109 comprises a superconducting cuperate. In another related embodiment, superconducting layer 109 comprises a high-temperature superconductor. High-temperature superconductors refers to those materials that behave as superconductors above about 77K or the boiling point of liquid nitrogen. In one embodiment the superconducting layer 109 deposited by any of the following techniques: thermal evaporation, electron-beam evaporation, sputtering or any combination thereof.

In one embodiment, devices of the present invention operate under cryogenic conditions, at temperatures which support superconductivity in superconducting layer 109. In one embodiment, devices of the present invention operate at any temperature, on condition that discrete superconducting regions form within the tapered NWs of the present invention.

Tapered NW 101 is also in contact with a surface of a 2-dimensional insulating layer 111 along a generating line (not shown) of the external surface of tapered NW 101. A conductive substrate 113, also referred to herein as an ‘electrically-conductive electrode’ or just ‘electrode’, is attached to the opposite surface of insulating layer 111. In one embodiment the insulating layer 111 is a dieletric. In one embodiment the insulating layer 111 is a high-dielectric material Non-limiting examples include silicon oxide, hafnium oxide, zirconium oxide. In one embodiment the insulating layer comprises an oxide. In a further related embodiment, insulating layer 111 is silicon oxide; in an additional related embodiment, electrode 113 is a charge-carrying semiconductor, a non-limiting example of which is doped Silicon; in another related embodiment, substrate 113 is a metal, a non-limiting example of which is Copper. In one embodiment, the substrate 113 is referred to as the substrate. In another embodiment, the substrate refers to the substrate 113 together with at least one insulating layer 111. In one embodiment the silicon is p-type. In another embodiment the silicon is n-type. In one embodiment, the insulating layer 111 is deposited by any of the following techniques: atomic layer deposition (ALD), evaporation, chemical vapor deposition (CVD), inductively coupled plasma (ICP) growth, plasma enhanced CVD, physical vapor deposition, chemical solution deposition, epitaxy, spin-coating or any combinations thereof. In some embodiments there is at least one insulating layer. In other embodiments additional layers are used to enhance adhesion of NWs to the substrate. In other embodiments additional layers are used to enhance coupling of NWs to the substrate.

Substrate 113 is set to ground potential via a connection 121. An adjustable voltage source 115 is connected to tapered NW 101 via a connection 125, and is settable to a tuning voltage V_{T} 117. Varying voltage V_{T} 117 alters the chemical potential of tapered NW 101; an increase of 1 volt in voltage V_{T} 117 increases the chemical potential of tapered NW 101 by approximately 1 MeV. The particular values of the voltage and the chemical potential are non-limiting examples. In a device, these values will be optimized to the materials used, the device structure and requirements of the user. In one embodiment the tapered NW 101 is connected at either end (103 or 105) with a connection 125. In one embodiment, both ends of the tapered NW 101 are connected as a source-drain junction. There are various ways to connect the tapered NW 101 to the connection 125. In one embodiment the tapered NW 101 is connected to the connection 125 via a connecting electrode. In a further embodiment, the connecting electrode is metallic. In another embodiment, the connecting electrode is fabricated by standard evaporation techniques onto at least one end of the tapered NW e.g., as electrode pads. In one embodiment, to produce a device comprising a tapered NW, the electrode pads are bonded (e.g., wire bonded) on a chip. In one embodiment, a device comprising a tapered NW forms at least one element of an integrated circuit. In one embodiment the substrate 113 is biased whereas the other terminal, connection 125 is grounded.

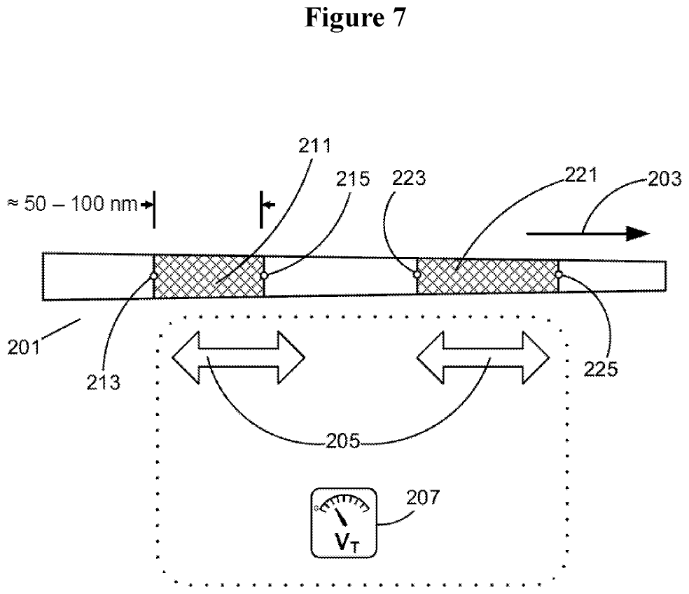

FIG. 7 conceptually illustrates a cross-section 201 of a tapered NW with an orientation 203, according to an embodiment of the present invention. Because of its taper, the entirety of NW does not become topologically superconductive. Instead, discrete (separated) regions of the tapered NW take on topologically superconductive states. In some embodiments, described herein, the device produces and manipulates superconducting regions within tapered NWs. In some embodiments, described here, the device manipulates the size and length of superconducting regions with tapered NWs. In some embodiments, described herein, the device manipulates the location of MZMs within tapered NW. FIG. 7 shows a region 211 of topological superconductivity has formed, with corresponding Majorana Zero Modes (MZMs) 213 and 215 on its boundaries. Another region 221 of topological superconductivity has formed, with corresponding Majorana Zero Modes 223 and 225 on its boundaries. Detection and imaging of MZMs may be accomplished using known techniques, such as by a Scanning Tunneling Microscope probe.

In one embodiment at least one topological superconducting region is formed in a tapered NW. In one embodiment the terms “topological superconducting regions” and “superconducting regions” are used interchangeably. As used herein “superconducting” refers to a set of physical properties that are observed in certain materials where the electrical resistance becomes negligible. In some embodiment the superconducting regions are topologically superconducting.

The length of the superconducting region can be varied and manipulated. Typically, a topological superconducting region typically cannot be shorter than the coherence length of the topological superconducting region. Furthermore, in one embodiment, the topological superconducting regions can be tuned by the tapering angle of the NW. The tapering angle refers to the angle between the NW (or nanofilament) axis 107 and a line extending from the surface of the tapered NW. In one embodiment a large tapering angle provides more discrete topological superconducting regions in comparison with a smaller tapering angle.

### Devices Comprising Tapered NWs for Control of MZMs

In one embodiment the present invention provides a device that comprises a tapered NW that supports discrete topological superconducting regions. Such a device is connected to incorporate a tapered NW, in a three-terminal source-drain-gate device, in some embodiments. In one embodiment the device comprises at least one back gate. In another embodiment the device comprises at least one top-gate. In another embodiment the device comprises at least one top gate and at least one back gate. In one embodiment, the tapered NW is disposed on a semiconducting substrate, separated by an oxide, wherein the tapered NW is connected with electrodes at either end as a source-drain junction. In one embodiment, the substrate is doped. In one embodiment the substrate is n-doped. In another embodiment the substrate is p-doped. In some embodiments, the material comprised in the tapered NW is doped. Applying a potential difference between the two terminals (i.e., a source-drain) connected at each end of the tapered NW, induces electron transport across the tapered NW. In some embodiments the electrodes connected to the ends of the tapered NWs are made of a conductive material. In some embodiments the electrodes further comprise an adhesion layer. In some embodiments, the electrodes further comprise an additional coupling layer. In some embodiments, the electrodes further comprise an additional insulating layer. Applying a gate modulates the electron transport through the tapered NW. In one embodiment the connecting electrodes are fabricated by evaporation onto either end of the tapered NW. In another embodiment, the connecting electrodes are fabricated by standard evaporation techniques onto at least one end of the tapered NW e.g., as electrode pads. In one embodiment, to produce a device comprising a tapered NW, the electrode pads are bonded (e.g., wire bonded) on a chip. In one embodiment, a device comprising a tapered NW forms at least one element of an integrated circuit.

In one embodiment the device further comprises side gates. Side gates are typically used to form tunnel junctions across the NW to measure spectroscopy.

In one embodiment the device further comprises at least one of the following additional materials: additional superconducting materials, non-superconducting materials, doped materials, semiconducting materials, dielectric materials, oxide materials, insulating materials, metals, 2DEGs, electron conductors, hole conductors, polymers or any combinations thereof.

According to embodiments of the present invention, the tapering of the tapered NWs is the physical 3-dimensional NWs which provides the discrete regions described above, and permits topologically superconductive regions to exist in a NW—and hence to support Majorana Zero Modes-without requiring tuning parameters to be exactingly precise. In one embodiment, tapered NWs are gate-defined. Therefore, embodiments of the present invention greatly facilitate quantum computing based on MZM-implemented qubits. In addition, embodiments of the present invention also provide further mechanisms to support quantum computing, as disclosed herein.

By adjusting a tuning voltage V_{T} 207 the locations of the discrete regions of topological superconductivity may be changed, as shown by arrows 205. The term “advance” herein denotes moving a region of topological superconductivity in the forward direction of the orientation of the tapered NW; the term “retract” herein denotes moving a region of topological superconductivity in the reverse direction of the orientation. In particular, increasing tuning voltage V_{T} 207 advances regions 211 and 221; decreasing tuning voltage V_{T} 207 retracts regions 211 and 221. It is appreciated that the Majorana Zero Modes on the boundaries of the topologically superconductive regions also move in the same fashion. According to certain embodiments of the present invention, this property of tapered NWs provides a means of moving MZMs from one location to another, without disrupting or altering them.

### Tapered NW Crosses

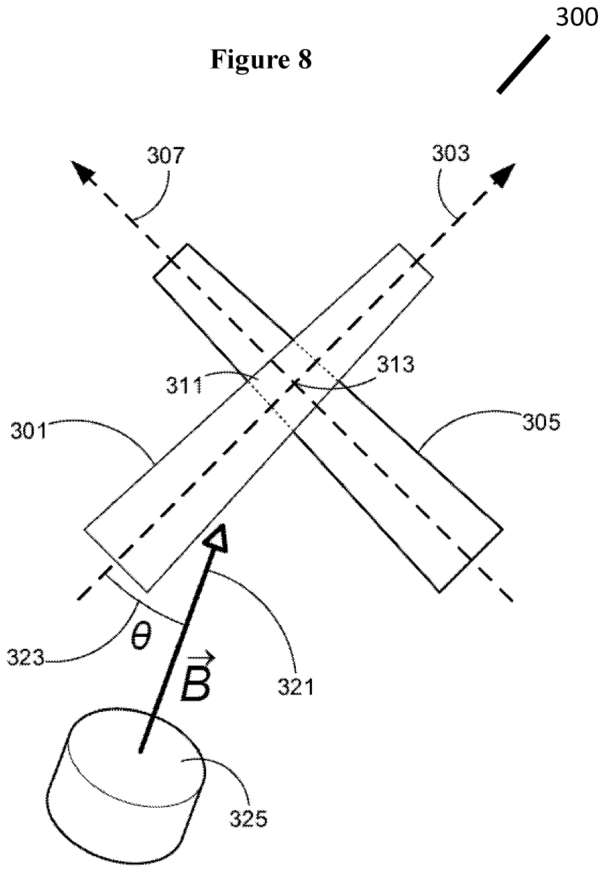

FIG. 8 illustrates a projected cross-section of an orthogonal device configuration 300 which is constructed of two tapered NWs devices 301 and 305, each of which has features as illustrated in FIG. 6. For simplicity and clarity, however, FIG. 8 shows only the projections of the respective tapered NWs without the supporting elements (such as superconducting layer 109, insulating layer 111, and substrate 113) as shown in FIG. 6. For added simplicity, the tapered NWs are shown as projections onto a single plane defined by the intersection of a generating line (not shown) of tapered NW 301 and a generating line (not shown) of tapered NW 305. These generating lines intersect at a point 313. Tapered NWs 301 and tapered NW 305 are in contact or quantum proximity at point 313. Tapered NW 301 has a projected orientation 303; NWs 305 has a projected orientation 307 which is substantially orthogonal to projected orientation 303. An overlap region 311 represents the location where the tapered NW can exhibit a quantum-mechanical overlap. FIG. 8 shows the projected orientations 303 and 307 both pointing upward, albeit at an angle. In one embodiment, the projected orientation of either 303 or 307, or both 303 and 307, is in the downward direction; all whilst tapered NWs 301 and 305 maintain their orthogonality. As used herein the term “substantially” with regards to “substantially orthogonal” may comprise a deviance, from purely orthogonal tapered NWs (e.g., projected orientation 307 and 303 forming a right-angle), of ±1%, or in some embodiments, ±2.5%, or in some embodiments, ±5%, or in some embodiments, ±7.5%, or in some embodiments, ±10%, or in some embodiments, ±15%, or in some embodiments, ±20%, or in some embodiments, ±25.

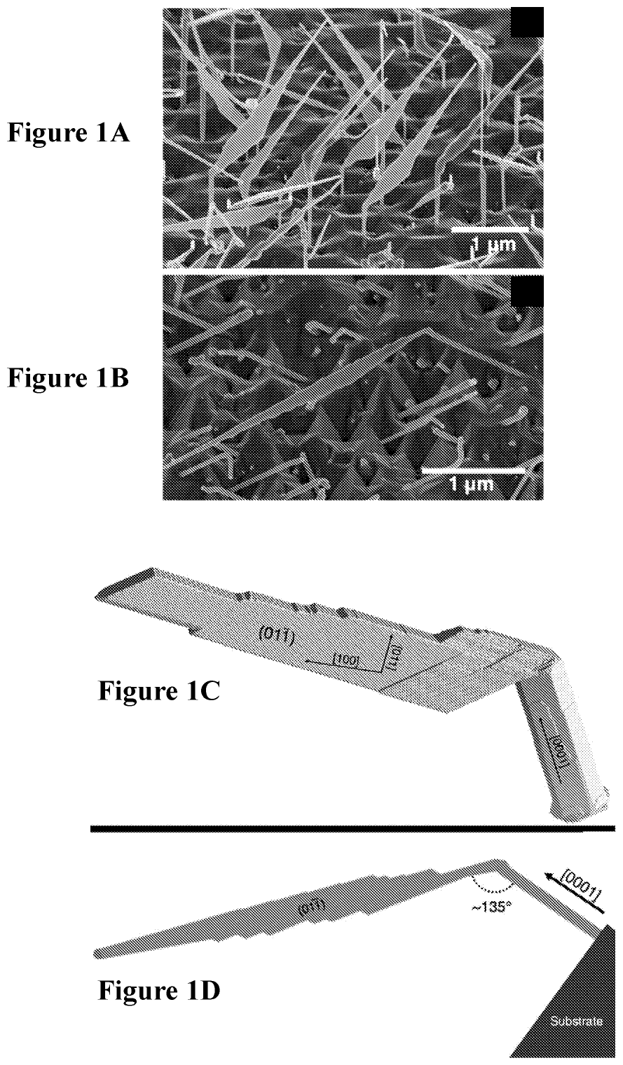

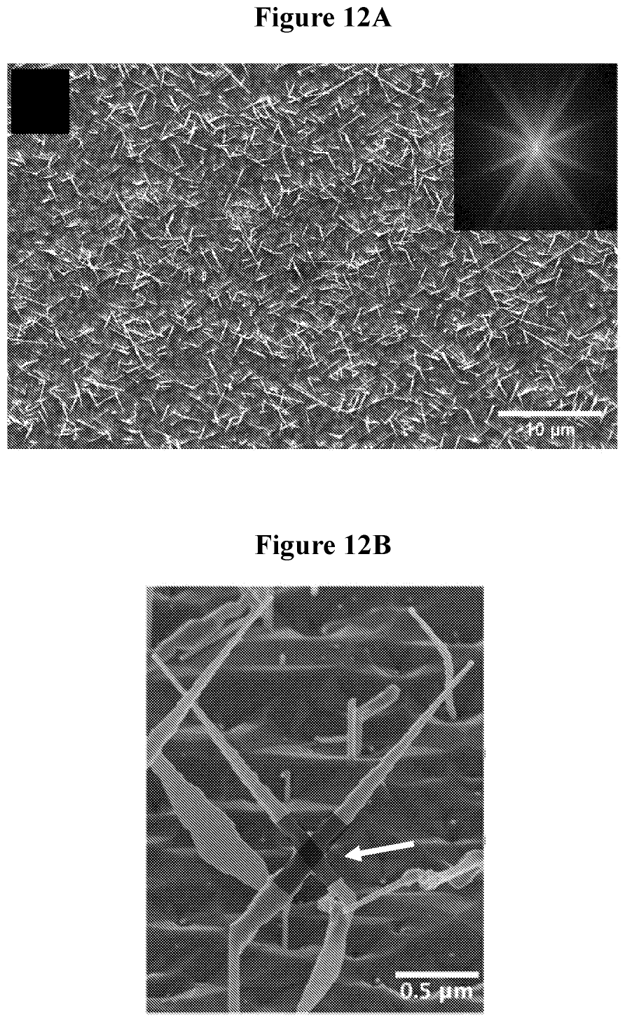

The formation of a tapered NW cross can be carried out in many ways. In one embodiment, two tapered NWs, disposed on a substrate, cross each other. In another embodiment, two tapered NWs emanating from a substrate, cross each other above the substrate. In another embodiment two kinked NWs cross each other, forming a tapered NW cross. In this embodiment, the two kinked NWs can intersect each other at any point along the kinked NW, as long as the projected orientation of each tapered NW portion that crosses is substantially orthogonal. FIG. 1 shows various examples of InAs kinked NWs, the fabrication of which are described in the examples. Furthermore, FIG. 12B shows an example of a tapered NW cross formed out of two kinked NWs that cross above the surface of the substrate. In one embodiment a fabricated tapered NW cross can be transferred to a device for use in computing. In one embodiment, tapered NWs are grown on substrates which comprise grooves, trenches or facets (or other), or any combination thereof, which provides a preferential growth direction of semiconducting NWs. In one embodiment grooves, trenches or facets are orthogonal, which facilitates the crossing of semiconducting NWs. In one embodiment standard fabrication and lithography techniques are used to pattern substrates to ensure that NWs form tapered crosses by controlling the direction in which they grow.

Kinked Tapered NWs or Nanoflags and Methods of their Production Thereof

Kinked tapered NWs (also referred to as “nanoflags” herein) are used, in one embodiment, to provide crossed tapered NWs. In such an embodiment the crossing of kinked tapered NWs can be at any location along the kinked tapered NW as long as the projected orientation of each tapered NW is substantially orthogonal (see FIG. 8), i.e., forming a cross. In one embodiment, the kinked NW grows out of the surface of the substrate, the first portion of which emanates from the surface and is non-tapered, whereas the second portion, extending from the first portion, is tapered. In another embodiment, both portions are tapered. FIGS. 1A-1B show kinked nanoflags emanating from a surface. FIG. 12B shows an instant where two kinked tapered NWs have crossed and are suspended above the surface of the substrate from which they were grown. In one embodiment, the kinked tapered NW comprises two parts: a first NW wherein a second NW emanates from the end of the first NW, and wherein the projected orientation of the first and second NWs are in different directions. In one embodiment the first NW is a ZB structure whereas the second NW is a WZ structure. In another embodiment the first NW is a WZ structure whereas the second structure is a ZB structure.

In one embodiment a kinked tapered NW comprises a semiconductor. In another embodiment the kinked tapered NW consists of a semiconductor. In one embodiment a kinked tapered NW comprises a semiconductor with a high spin-orbit coupling. In another embodiment the kinked tapered NW consists of a semiconductor with a high spin-orbit coupling. In one embodiment the material comprising the kinked tapered NW is selected from InAs or InSb. In one embodiment the tapered NW comprises a doped semiconducting material.

It is important to note, as mentioned herein, that crossed tapered NWs can be formed in many different ways. The present disclosure provides several non-limiting examples and tapering NWs but is not limited to the present examples alone. Generally, tapered NWs can be disposed on a surface, but they can also be embodied as gate-defined structures. The invention is not limited to the method in which such tapering, or crossing is achieved; all of which are considered within the scope of the presently disclosed subject matter.

### A Method of Producing Kinked Tapered NWs

In one embodiment, kinked NWs are produced by molecular beam epitaxy (MBE). In some embodiments “kinked NWs” are also referred to as “kinked tapered NWs”. More specifically, and in another embodiment, kinked NWs are produced in Au-assisted vapor liquid solid (VLS) MBE. First, a semiconducting substrate is provided. In one embodiment, the semiconducting substrate comprises InAs or InSb. In another embodiment, the semiconducting substrate consists of InAs or InSb. In one embodiment the orientation of the semiconducting substrate is selected from (100), (111) or (001). In some embodiments, the substrate is doped. In some embodiments the substrate is n-doped. In other embodiments the substrate is p-doped. In some embodiments, the substrates is cleaned in organic solvents before any deposition processes. In some embodiments, the substrate is cleaned by plasma ashing and/or UV-ozone surface treatment. After cleaning, and in one embodiment, before placing the substrate in the MBE chamber, the substrate undergoes oxide blow-off. A thin film (also referred to herein as a layer) of a catalyst, for example Au, is then evaporated onto the substrate. In one embodiment the Au-layer has a thickness of less than 1 nm. In other embodiments the thickness of the Au-layer ranges between 1-2 nm. in other embodiments the thickness of the Au-layer ranges between 2-10 nm. In some embodiments the Au deposition produces a discontinuous layer of gold on the surface of the substrate. In other embodiments the Au deposition produces Au droplets on the surface of the substrate. In other embodiments the Au deposition produces a continuous layer on the surface of the substrate. In some embodiments the substrate, comprising the Au-film is further annealed.

Next, the Au-comprising substrate is heated to an elevated temperature. The temperature of the elevated temperature will be different for each substrate and material that is used; the temperature should be optimized for each material and substrate. In one example, InAs substrates coated with thin Au films are initially heated to about 600° C. In a further embodiment, the elevated temperature occurs under As overpressure. The material used in the overpressure will depend on the NW and substrate material used. In one embodiment the As/In overpressure is about 100. In one embodiment the As/In overpressure is about. In one embodiment the As/In overpressure is about. The substrate is subsequently cooled by about 100° C. after which an In shutter is opened. In one embodiment the rate of cooling at this stage is about 100° C. per hour. At this stage, and in one embodiment, patterns form on the substrate, for example on the surface of an InAs substrate, which comprises facets oriented in two opposite directions e.g., two opposite (111) facets. In some embodiments, the substrate is patterned such that it comprises multiple facets and/or facets oriented in opposite directions. In one embodiment the NWs emanating from the Au nucleation sites are rounded. NWs then emanate from the Au nucleation sites (or whichever catalyst is used), i.e., sites on the Au-film, in two opposite directions. Thus far, the method provides a method of producing uni-directional NWs.

In one embodiment, lowering the temperature of the MBE process changes the direction of growth of the NW, causing a kink in the growing NW. In one embodiment the change of temperature required to cause a kink in a NW is 100° C. In one embodiment the change of temperature required to cause a kink in a NW is 200° C. In one embodiment the change of temperature required to cause a kink in a NW is 300° C. In one embodiment, to change the direction of growth of the NWs the temperature is lowered by about 100° C., for example from 500 to 400° C. In one embodiment the rate at which the temperature is lowered is 10° C. per minute until a temperature of 300° C. is reached. At this final temperature, and in one embodiment, the NW growth is maintained for 1 to 2 hours. In some embodiments, the temperature is maintained for 2 to 5 hours.

This section discloses methods of producing kinked tapered NWs. In one embodiment this same process also produces crossed kinked tapered NWs. Some of the kinked tapered NWs will intersect forming crossed kinked tapered NWs. In one embodiment, the yield of produced crossed kinked tapered NWs is increased by optimizing the channels of growth of NWs along facets on the substrate. In one embodiment the yield of produced crossed kinked tapered NWs is increased by optimizing the temperature, rate of cooling, starting and finishing temperature, duration at a particular temperature or a combination thereof.

### External Magnetic Fields

According to certain embodiments of the invention, a uniform external magnetic vector field \vec{B} 321 is applied by a magnet 325 whose strength and orientation are adjustable. In one embodiment the magnet field is provided by a permanent magnet. In another embodiment the magnetic field is provided by an electromagnet. In one embodiment the magnet is provided with a means to point in different directions In one embodiment the magnet is provided with a means to rotate. Typical values of the magnitude of magnetic field \vec{B} 321 are in the hundreds to thousands of Gauss but must not be strong enough to quench the superconductivity of the superconducting layer (layer 109 in FIG. 6). Magnetic field \vec{B} 321 affects the size of the topological superconducting gap, and hence the length of regions of topological superconductivity in both tapered NW 301 and tapered NW 305. However, it is the component of the magnetic field parallel to the orientation of a tapered NW which affects the size gap and the length of the topological superconducting regions. Thus, for magnetic field \vec{B} 321 having an intersection angle θ 323 with projected orientation 303, the component of magnetic field \vec{B} 321 along the orientation of tapered NW 301 equals (to a good approximation) B cos θ, while the component of magnetic field \vec{B} 321 along the orientation of tapered NW 305 equals (to a good approximation) B sin θ. Therefore, according to various embodiments of the present invention, changing the magnetic field angle θ 323 alters the relative lengths of topological superconducting regions in tapered NW 301 with respect to that of tapered NW 305.

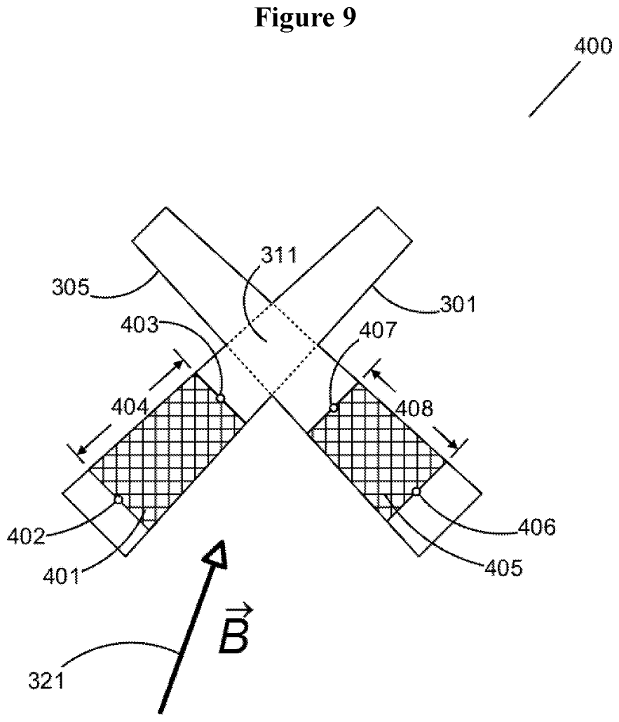

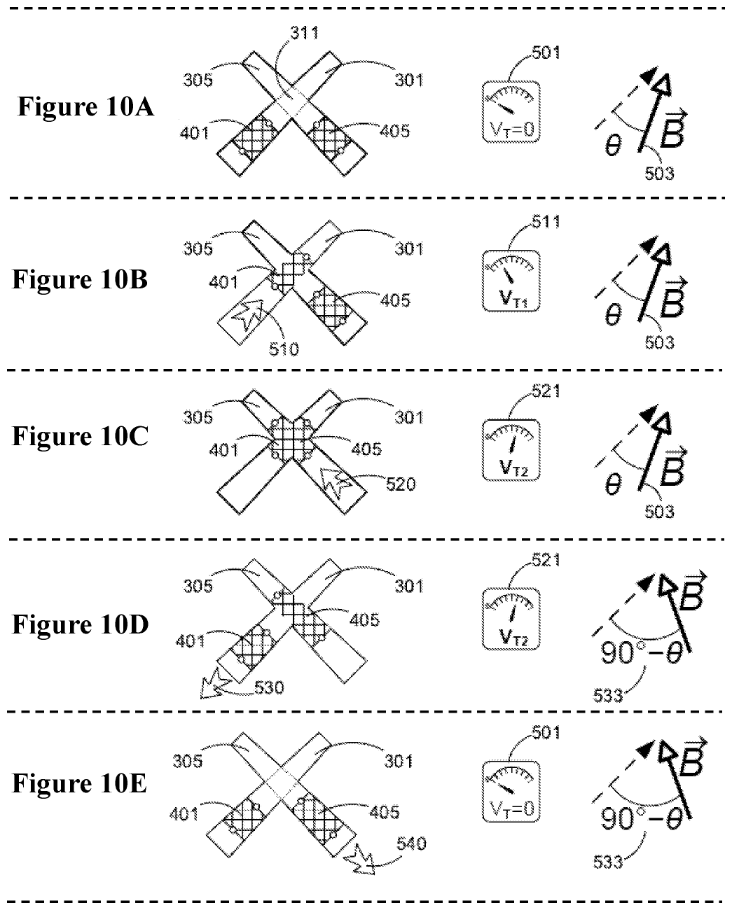

FIG. 9 illustrates (in projection onto the plane described previously for FIG. 8) an orthogonal two-tapered NW device 400 (similar to that shown in FIG. 8), conceptually showing a region of topological superconductivity 401 with corresponding Majorana Zero Modes 402 and 403; and a region of topological superconductivity 405 with corresponding Majorana Zero Modes 406 and 407. As noted above, magnetic field 321 alters the relative lengths of the topological superconducting regions. Thus, a length 404 (of region 401) will be greater than a length 408 (of region 405). This configuration as shown in FIG. 9 represents an initial condition for the device, as further disclosed below, and as shown in FIG. 10A through FIG. 10E, to illustrate the operation of a swap gate according to certain embodiments of the present invention, as disclosed below:

FIG. 10A shows a schematic illustration of braiding of Majorana end modes in a tapered NW cross using a single global back-gate. Rotation of in-plane magnetic field changes the extent of the topological segment (its component along the NW axis does not contribute to the Zeeman gap) and variation of the chemical potential transports the topological segment. The central column follows the positions of the two topological segments according to the magnetic field and potential shown in the left hand column. The right hand column follows the relative position of the four end Majoranas showing braiding of a pair.

FIG. 10A conceptually illustrates the tapered NW device configuration of FIG. 9, in an initialization state wherein tuning voltage V_{T} 501 is set to 0 volts; and the set orientation 503 of magnetic field \vec{B} is asymmetrical with respect to tapered NW 301 versus tapered NW 305. In this magnetic field configuration, θ<45°, so that cos θ>sin θ, and as a result, the magnetic field enhances the advancing and retracting of region 401 of tapered NW 301 over that of region 405 of tapered NW 305.

FIG. 10B shows a first step in the operation of the swap gate—an increase of tuning voltage V_{T1} 511 to a non-zero voltage, causing an advance 510 in region 401 of the superconducting region in tapered NW 301 into overlap region 311. As noted previously, region 405 of tapered NW 305 is not advanced significantly because of orientation 503 of the magnetic field.

FIG. 10C shows a second step in the operation of the swap gate—a further increase of tuning voltage V_{T2} 521 to a higher voltage (V_{T2}>V_{T1}), causing an advance 520 in region 405 of tapered NW 305 into overlap region 311.

FIG. 10D shows a third step in the operation of the swap gate—a change in direction 533 of magnetic field \vec{B}, where θ>45°, so that cos θ<sin θ, and as a result, the magnetic field enhances the length of region 405 of tapered NW 305 over that of region 401 of tapered NW 301. The shortening of region 401 on account of the reorientation of magnetic field \vec{B} causes an effective retraction 530 of region 401 out of overlap region 311 toward its original location in tapered NW 301.

FIG. 10E shows a fourth and final step in the operation of the swap gate—a reduction of tuning voltage V_{T} 501 to 0 volts, resulting in a retraction 540 of region 405 out of overlap region 311 and into to its original location in tapered NW 305.

It is noted that the sequence of superconducting region retracting resulting from steps in FIG. 10D and FIG. 10E is not the reverse of the sequence of superconducting region advancing that resulted from steps in FIG. 10B and FIG. 10C. A true reverse would be a “last-in, first-out” (LIFO) sequence. Instead, however, the sequence is a “first-in, first-out” (FIFO) sequence, which is not a reversal. The overall effect of the FIFO sequence of FIG. 10A to FIG. 10E is that the qubit originally encoded by the MZMs in region 401 is now in region 405, and the qubit originally encoded by the MZMs in region 405 is now in region 401, i.e., the qubits of region 401 and region 405 have been swapped by gate device 400 (FIG. 9).

### Quantum Computing Devices Comprising Tapered NWs and Crossed Tapered NWs

Methods of braiding MZMs are detailed herein wherein the key component is the use of crossed tapered semiconducting NWs. In order to realize the braiding of said MZMs the presently disclosed subject matter provides a device comprising at least one crossed tapered NW. As schematically illustrated in FIG. 6 each individual tapered NW can be connected using standard electronics.

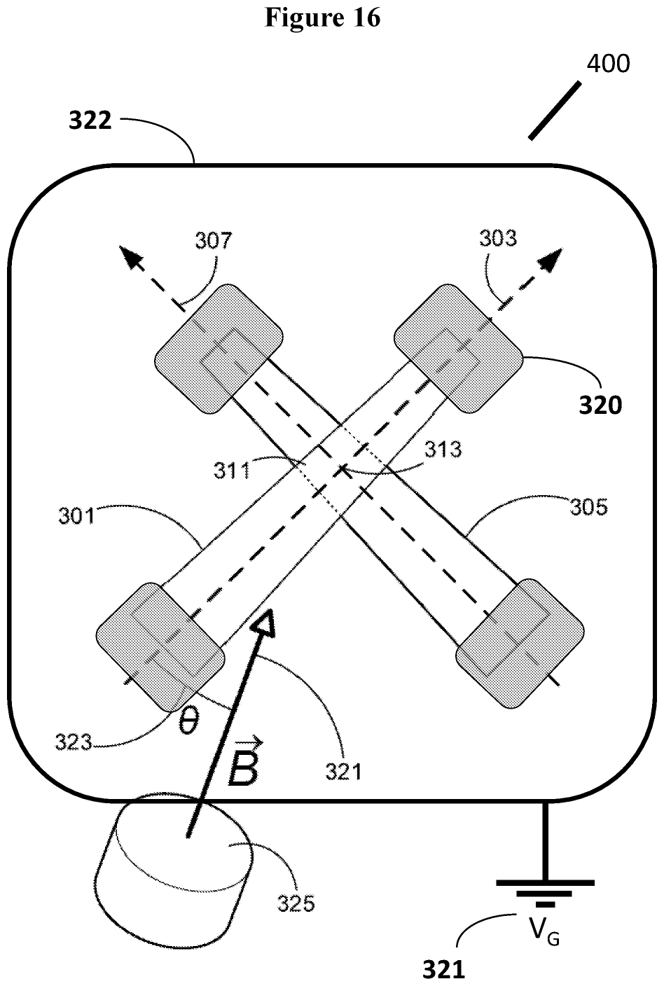

FIG. 16 shows a schematic illustration of the crossed tapered NW 300 of FIG. 8 incorporated into a quantum computing device 400 for braiding of MZMs. For simplicity and clarity, however, FIGS. 8 and 16 shows only the projections of the respective tapered NW without the supporting elements (such as superconducting layer 109, insulating layer 111, and substrate 113) as shown in FIG. 6. For added simplicity, the tapered NWs are shown as projections onto a single plane defined by the intersection of a generating line (not shown) of tapered NW 301 and a generating line (not shown) of tapered NW 305.

Four conductive pads 320 shown, positioned at both ends of tapered NW 301 and tapered NW 305. In one embodiment the conductive pads comprise a metallic material. In one embodiment the conductive pads consist of metallic material. In one embodiment the conductive pads further comprise an adhesion later. In one embodiment the conductive pads are wire bonded in a permanently contacted device. In one embodiment the device 400 forms one element of an integrated circuit. In one embodiment the device 400 forms one element of a printed circuit board (PCB).

The device 400 comprising the crossed tapered NW 300 is set on a substrate, embodiments of which are described herein. For the sake of clarity and simplicity of FIG. 16, the substrate 322 is depicted without layers. However, as described elsewhere, and in some embodiments, the substrate 322 comprises a semiconducting material and at least one insulating layer upon which a crossed tapered NW 300 is disposed thereon. In one embodiment, the device 400 comprises a back gate 321. An expert in the art is familiar with back-gating a device disposed on a substrate.

In some embodiments, crossed tapered NW 300 in the quantum computing device 400 is a gate-defined crossed tapered NW. An expert in the art is familiar with how to achieve gate-defined nanostructures. In one embodiment the gate-defined nanostructures are coupled to a 2D electron gas (2DEG). In some embodiments, the device 400 comprise a magnet 325 whose strength and orientation are adjustable.

### Concluding Remarks

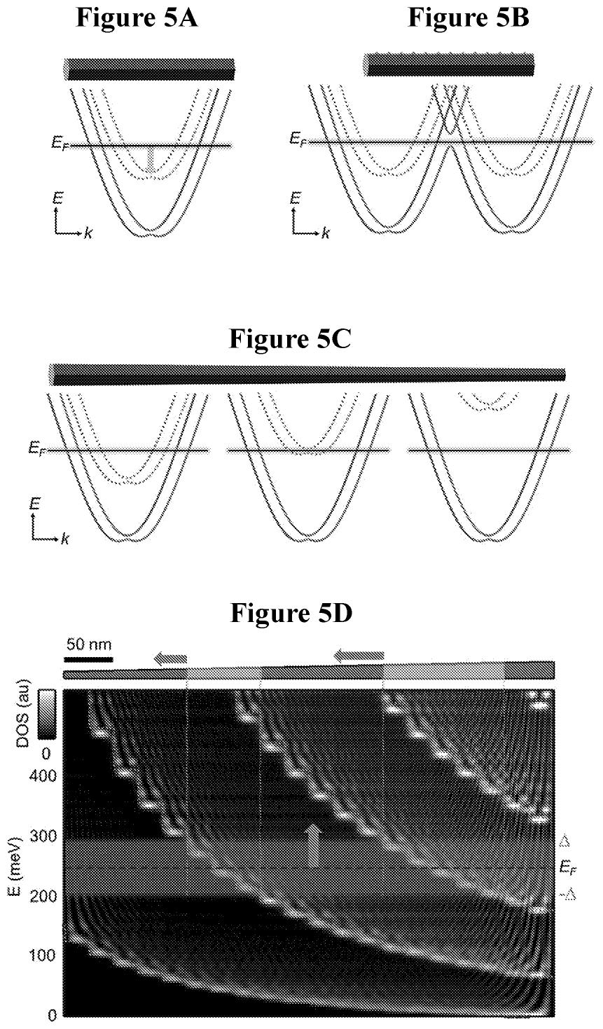

In the presently disclosed subject matter, tapered NWs that also host an atomic-scale superstructure on their surfaces have been disclosed. Intriguingly, these provide two complementary methods for engineering the Kramer's degeneracy within the vicinity of the chemical potential. First, a periodic superlattice potential folds the sub-band spectrum. This gives rise to additional Kramer's degeneracies at the edges of the folded Brillouin zone (FIG. 5b). An atomic periodicity of four was calculated to be optimal for inducing such Kramer degeneracies in proximity to the chemical potential. Second, as the NW diameter gradually changes along its axis, it consequently varies the sub-band level spacing. This pushes Kramer's degeneracies across the chemical potential at certain segments along the NW (FIG. 5C). Both methods alleviate or minimize the need for back-gate tuning to induce the topological superconducting phase, as they bring Kramer's degeneracy close to the chemical potential. Moreover, for the second approach the application of a uniform back-gate would result in a smooth variation of the segments, along which the superconducting gap would overlap with the Zeeman gap. This would result in transportation of the topological segment along the NW (FIG. 5D), allowing an unprecedented level of control over the MZMs.

Tapered NW crosses provide a route to perform braiding operations with the minimal required number of gates (see FIG. 12), thus reducing the complexity and improving the scalability of Majorana networks. Remarkably, it was found that both these approaches are realized in tapered NWs.

Tapered, so-called nanoflags, InAs NWs that host an atomic-scale superstructure on their surfaces are presented. The present subject matter discloses their growth and electronic structure. InAs NWs, which nucleate on a (001) surface with a pure wurtzite (WZ) structure, are forced to diverge from the direction by experiencing low temperature and high supersaturation. The new growth direction induces a change from WZ structure with a typically rounded shape to a zinc-blende (ZB) tapered rectangular nanoflag with two broad (011) facets. This rectangular shape enables careful STM measurements of the (011) surface of the nanoflag. Studies using SEM, TEM, and STM were correlated and supported by kinetic Monte Carlo MC simulations, shedding light on the unique surface structures composed of ordered rows of atoms. In the tapered NWs, the quantized spectrum evolves with the varying NW diameter. The tapered global structure and the microscopic superstructure provides two complementary methods for engineering the Kramer's degeneracy to within the vicinity of the chemical potential. Thus, nanoflag InAs NW structures are suitable platforms for the search and manipulation of MZMs.

### Example 1

### Tapered NW Morphology and Structure

Kinked InAs NWs were grown by Au-assisted vapor-liquid-solid (VLS) molecular beam epitaxy (MBE) on the (001) plane, which produced rounded reclining NWs that emerged in two opposite (111) directions (see FIGS. 1A and B). By lowering the growth conditions (by 100° C. in the present example), such NWs are forced to kink and change their growth direction, structure, and shape. The kinking of the stem growing in the (111) direction into the new growth direction induces a significant change in the NW morphology. They bend into the direction perpendicular to the axis, i.e., a (mnn) direction with m >>n, assuming a change from the wurtzite (WZ) structure to the zinc-blende (ZB) one.

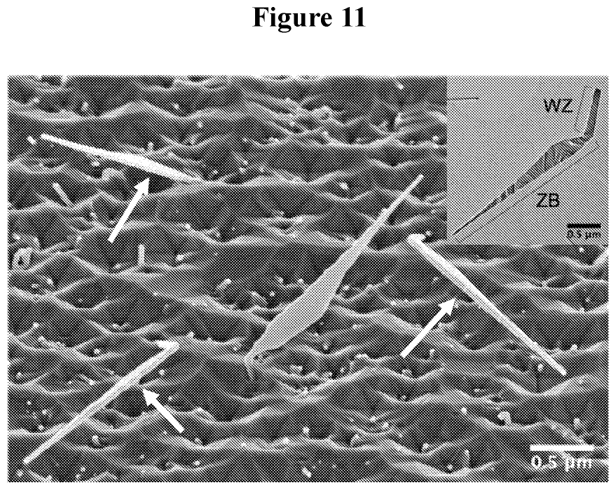

The rectangular nanoplate that forms after the kink is characterized by two narrow facets (about 40 nm thick) and two broad facets, as shown in FIG. 1 (see also FIG. 11). The edges of the two broad facets are terminated by prominent macro steps of inclined (111) facets. The broad facets gradually converge into a very narrow square-shaped tip (about 30 nm in both thickness and width). During the growth, the Au droplets shrink into significantly smaller droplets beyond the kink. This is a result of the temperature decrease, which increases the supersaturation in the droplets. The kinking does not take place in any particular direction (FIG. 12A). The necessary condition for kinking the InAs NWs is lowering growth temperature (100° C. in this work). It is noted that the smaller the NW's diameter, the higher the temperature at which kinking will occur.

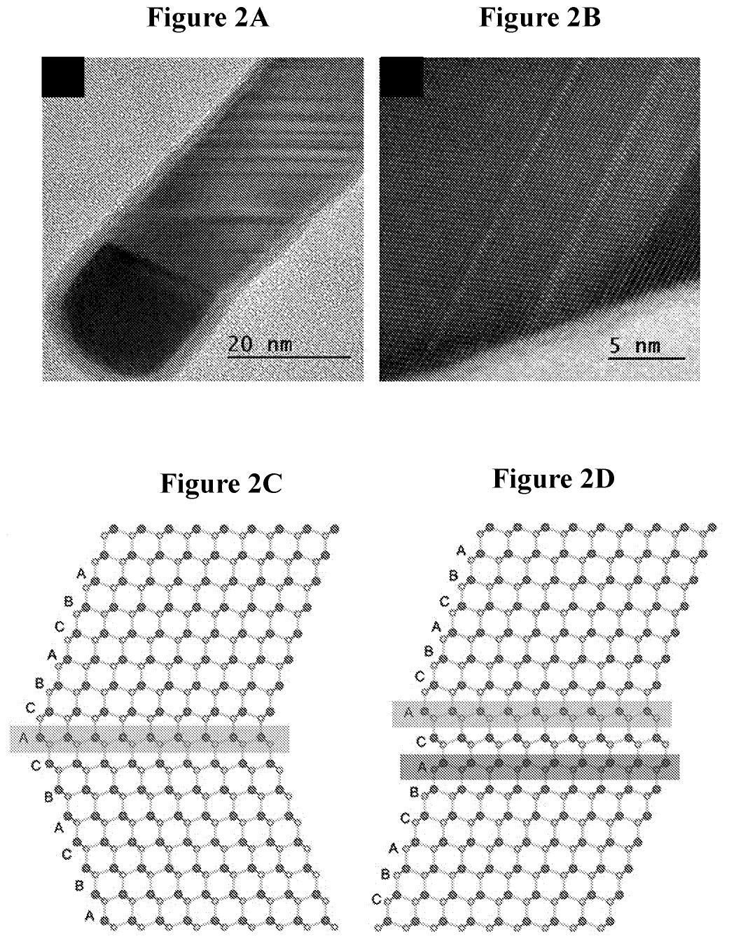

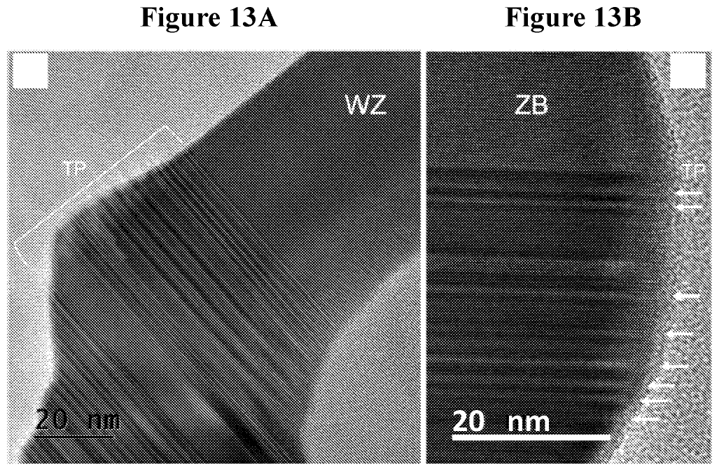

A broad neck with occasional diagonal double twin planes (TP) forms between the WZ stem and the ZB nanoplate (see FIG. 13). The double twin planes are visible in high-resolution transmission electron microscopy (TEM) images, as shown in FIGS. 2A and 2B. Schematic illustrations of a single and a double twin plane are shown in FIGS. 2C and 2D, respectively, which clarify the atomic layers ordering.

These NWs resemble so-called nanoflags. Occasional crosses form by the intersection of two nanoflags (FIG. 12B). Such an intersection is presented herein as a skeleton for the formation of a device that can display the braiding of Majoranas (FIG. 10), as discussed herein.

### Example 2

### Simulation of Tapered NW Growth

To explain the shape and structure of the kinked InAs NWs, their growth was simulated using the MC method. Simulations start by assuming an external flux of particles approaching the surface with given frequency. As the VLS growth of the InAs NWs in MBE is conducted at a high As overpressure, it is assumed that indium is the element that fully controls the growth. Thus, in the calculations the external flux consists of only one type of particle, i.e., indium atoms. The In adatoms diffuse along the surface and can either nucleate, creating clusters, or attach to steps that exist on the surface. Each of these processes is governed by a different probability. An increased probability for forming clusters is assumed on a 20 lattice units wide part of the surface to simulate the presence of a gold droplet, which catalyzes the NW growth. It is also assumed that the diffusing particles can easily climb up a step on the surface but that coming back is forbidden. In such a way the process of capturing adatoms is modelled on the part of the surface simulating the gold spot. NW growth starts from the nucleation of a seed consisting of four neighboring In atoms on the flat surface within the gold droplet. Each new layer on top of the growing NW also starts with a seed of nucleation. Such a modeling scheme allows simulation of the process of Au-assisted NW growth.

In this present disclosure, the growth of a NW vertical to the (111) surface is first simulated, forming a WZ structure. The attachment of adatoms on the hexagonal top of the NW is equally probable in all six directions, with the rate of 0.09. In the simulation, this NW was grown along the [0001] axis for 33 000 MC steps. As a result, a 180 lattice units high regular hexagonal NW was obtained. Next the NW is bent in that lowering the temperature changes the balance between the free energy of the gold droplet and the chemical potentials of different surfaces. Thus, the gold droplet can move to the side of the NW. The new NW beneath such a gold spot would grow in a different direction with respect to the original one. To include this process into the calculations, the area that simulates the gold droplet is moved to the side of the NW and the whole structure was rotated to have the vertical axis in the [311] direction. Then, performing the growth process upward, a kinked NW is obtained pointing in a direction laying between the [311] and [100] axes (FIG. 1C). At the same time, the geometry of the new surface induces a new crystal structure, namely ZB. The new structure is modelled by assuming a diffusion coefficient twice as small as that in the first stage. This is in line with the reduction of temperature, which causes the NW bending in the experiment. The lower growth temperature and slower diffusion increases the nucleation probability as well as the particle's likelihood to attach to a step. Moreover, to obtain a flat rectangular NW with wide (110) facets, a 103 larger attachment probability in the [100] is assumed, than that in the [110] direction. The diffusion of adatoms along the surface sets the time scale of the simulation. Thus, this part of the simulation was run for 300 000 MC steps, nine times longer than the first one.

### Example 3

### Spectroscopic Characterization of Tapered NWs

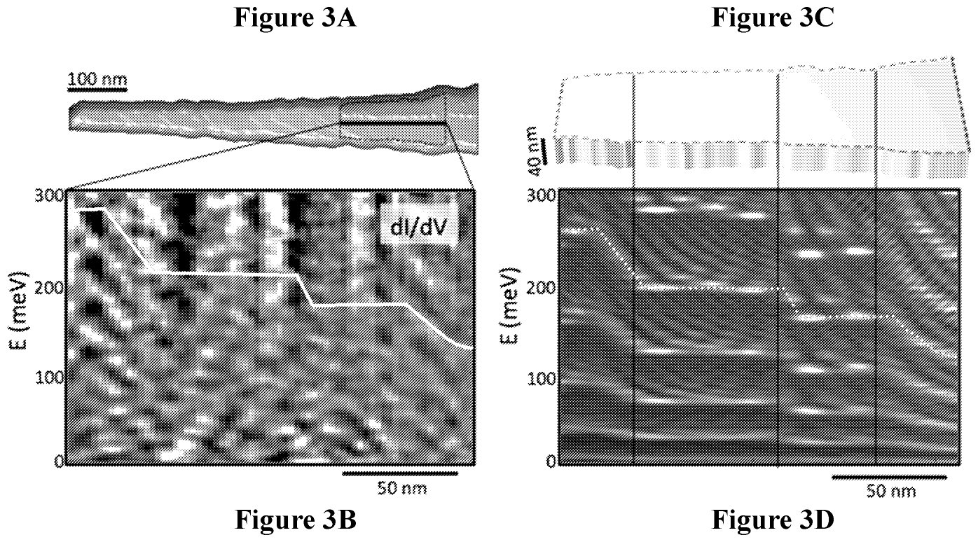

The obtained rectangular cross-section of the nanoflag with its flat facets renders the kinked NWs highly suitable for scanning tunneling microscopy (STM) studies. NWs were harvested onto an Au substrate and transfer in a designated ultrahigh vacuum suitcase. The results of the STM measurements showing the topography and demonstrating the impact of tapering on its energy spectrum are presented in FIG. 3.

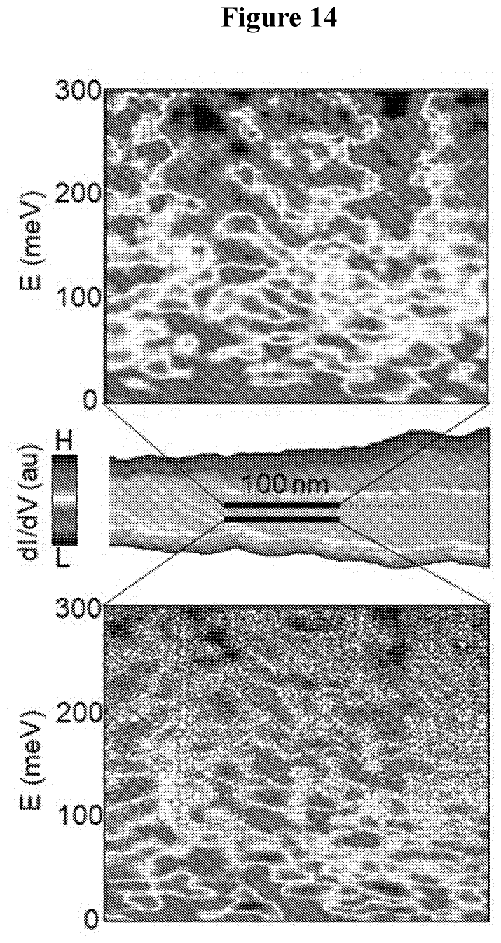

The tapered topography of the NWs is clearly visible in FIG. 3A along with its irregularities. A milder thickness decrease was also imaged by the sequence of step edges on the top flat terrace. The evolving local density of states was mapped over an atomically flat linecut along the NW axis in FIG. 3B. The fairly regular bright spots at any point along that line stem from Van Hove singularities at sub-band extrema. The local irregularities of the tapered NW boundaries, as well as the surface roughness on the atomic scale, result in a complex evolution of the spectrum. Nevertheless, along the line scan this rather regular pattern evolves in energy in response to the overall varying boundaries of the tapered NW. These main spatial patterns are reproduced at different positions across the tapered NWs (see FIG. 14).

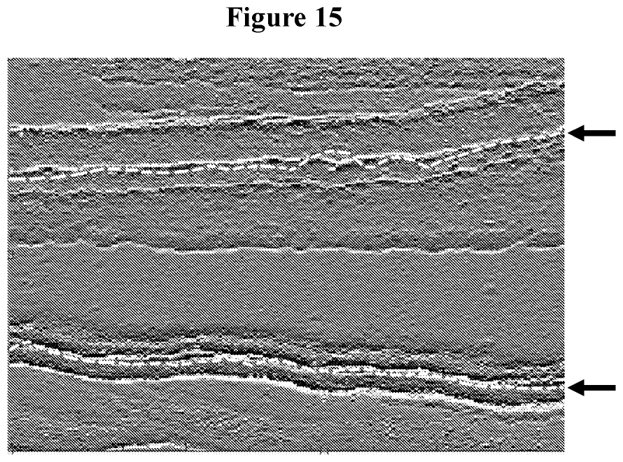

Detailed NW boundaries were modelled along this segment (FIG. 3C) and the density of states response was simulated in Kwant (FIG. 3D extracted from the topography in FIG. 15). Four distinct sections were identified in the topography with clear spectral correspondence. In the right and left most sections, the level spacing gradually increases as the NW gradually shrinks. Along the central two sections, the width is fixed but changes abruptly at a certain point, as does the level spacing. Those spectral trends in the simulation (red line in FIG. 3D) are exhibited by the tapered NW spectroscopically mapped in FIG. 3B. This exemplifies how the quantized spectrum of a NW can be engineered by modulating its boundaries. However, more regular tapering is required to achieve the gradual and monotonic evolution of the spectrum along the NW axis, which supports the smooth control and transportation of topological superconducting segments along it.

### Example 4

### Atomic-Scale Superstructure in Tapered NWs

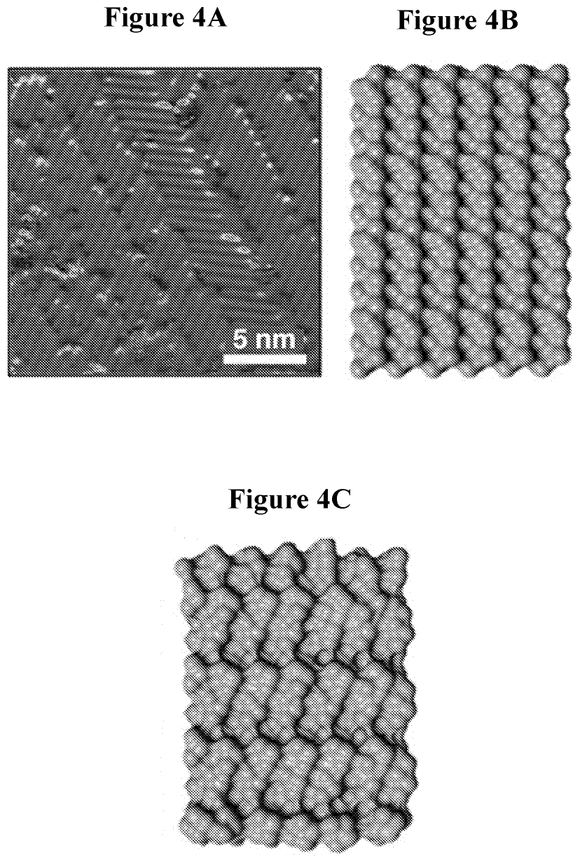

STM topography further discovered a self-ordered atomic pattern at the surface of the kinked NWs. It consists of four-atom chains that form rather regular rows (FIG. 4A). A similar pattern was not detected in TEM (FIG. 2), which is a bulk probe, suggesting it is strictly a surface phenomenon. This pattern resembles the surface reconstruction for differently oriented surfaces in several III-V compounds in the presence of excessive ions, either cations or anions. Thus, as the MBE growth of the disclosed NWs was conducted under As overpressure, the reconstruction pattern observed in the STM relates to the excess As ions at the surface. It is noted that As termination of the (110) surface of GaAs indeed leads to a lower energy than the cationic one.

To test the hypothesis that the patterns at the InAs (110) surface of the nanoflags are related to As adatoms, minimization procedure was performed within the LAMMPS molecular dynamics simulator Tersoff potential. For this procedure, a crystal composed of 12×12×8 atomic layers with a ZB structure and atomic distances typical of InAs was arranged. The top surface was a (110) plane, over which 144 As adatoms were placed in regular rows. The number of additional As atoms is equal to the number of atoms in one monolayer. The initial arrangement is shown in FIG. 4\vec{B}, where only As ions, denoted by yellow balls, are visible. Periodic boundary conditions were set in the x- and y-directions, while in the z-direction the boundary was left free. Two layers at the bottom of the crystals were kept immobile, whereas a large space of three interlayer distances was left above the crystal surface. This distance allowed atoms to move freely on top of the surface. The crystal structure was relaxed using a conjugate gradient algorithm. FIG. 4C shows the configuration after relaxation. After such a reconstruction, As atoms form regular chains that were inclined to the initial rows. The consecutive chains of As atoms were well separated from one another. Like in the STM picture shown in FIG. 4A, the pattern breaks periodically along [100] lines. At each such break, the whole next chain setup was shifted. The breaking lines, which appear both in STM pictures and in the simulations, were formed in order to relax the strain arising from the mismatch between the InAs (110) surface and the As chains.

In FIG. 4A, one can also notice a change of the orientation of the As chains at some line that is not visible in the simulations, suggesting that the orientation changes of the surface pattern originate in the bulk ordering beneath the surface. Indeed, the TEM images (FIG. 2) confirm that the structure observed in the STM images were present only at the surface, whereas below it a very uniform crystal structure was visible. Moreover, plains were identified along which the surface pattern changes its orientation, originating in the bulk ordering. Finally, it should be noted that the angle between the two orientations of the chains indicates that the real crystallographic directions of the As chains are either the {211} type or the {111} type. The present results confirm that the pattern observed on the (110) surface of the nanoflags was indeed related to the As adatoms.

Remarkably, a 4 unit cell potential induces the Brillouin zone folding needed to have a Kramer's degeneracy right at the vicinity of the chemical potential in InAs NWs. Hence, its presence fully alleviates the need to further tune the chemical potential or will at least substantially reduce the amount of tuning needed. The combination of superlattice folding with mild tapering may be ideal to maximize the benefit of both.

### Example 5

### Method for Growing InAs Kinked NWs

The high purity InAs kinked NWs were grown by Au-assisted vapor liquid solid (VLS) molecular beam epitaxy (MBE) in a Riber 32 system with vacuum in the low 10⁻¹¹ Torr. A very thin (<1 nm) layer of Au was evaporated in-situ on the (001) InAs at ˜100° C. right after oxide blow-off in a separate chamber attached to the MBE growth chamber. For the general NWs growth on the (001) the substrate was first heated to ˜600° C. under arsenic overpressure (As/In ˜100), where the gold droplets form, then gradually cooled to the growth temperature ˜400° C. Midway between the two temperatures the In shutter (˜5e-7) was opened. During this cool down process, the (001) surface initially becomes covered with craters comprised of two opposite (111) facets, which facilitate the nucleation of typically rounded NWs that grow in two opposite directions. NWs growth in the direction is maintained for an hour after which the substrate temperature is reduced by 100° C. at a rate of 10° C. per minute while growth continues all the way to ˜300° C. The low temperature growth continued for 1-2 hours for different samples in order to extend the “plate” length.

### Example 6

### Braiding in Tapered NW Crosses

Since the nanoflag NWs orient in various directions (FIG. 12A) occasionally crosses of such tapered NWs occur, as the one in imaged FIG. 12B. Such tapered NW crosses may support a simple and scalable protocol for braiding MZMs across them. It relies on two main ingredients: the first is the smooth transportation of Majorana modes by gating, which is dictated by the local diameter. The second is that the Zeeman gap is not contributed by the magnetic field component perpendicular to the NW and parallel to the substrate. Therefore, for perpendicularly crossing NWs rotation of an in plane magnetic field would make the Zeeman gap in one arm grow while the gap in the other would shrink.

Consequently, the rotation results in an enlarged topological segment on one arm and a shrinking segment on the other, respectively. Combination of both enables the following braiding sequence, sketched in FIG. 10: at stage (i) both topological segments are removed from the cross. At stage (ii) application of a backgate transports both segments towards the cross so that one segment crosses it while the second does not (dictated by the local tapering). At stage (iii) rotation of the in-plane magnetic field enlarges the segment outside the cross till it eventually crosses the intersection. At stage (iv) the back-gate is reversed such that the topological segment that entered first exits the intersection. At stage (v) the magnetic field is rotated back such that the system returns to stage (i) up to an exchange of the Majorana modes that has occurred. This constitutes a braiding operation that requires a single gate per a crossed tapered NWs intersection. For a network of tapered NWs, the application of the local gates can be considered as activation of the qubits to be braided, while the rotation of a global in-plane field performs the braiding for those gate activated ones. Those qubits that are not activated are spectators that will not undergo braiding by the rotation of the field.

### Example 7

### Spectroscopic Characterization of Tapered NWs

FIG. 14 shows two spectroscopic linecuts taken at slightly distant locations across the tapered NW show similar gross features. The top linecut is cropped from a full linecut shown in FIG. 3). The bottom one (in FIG. 14) was taken about 5 nm below it over the same distance of 100 nm. Their similarity signifies that the dispersing features result from the overall confinement while local disorder changes only fine details.

Regarding FIG. 15, the nanowire profile was extracted for Kwant simulation by following the sharp peaks in the spatial derivative of the NW's topographic image. 100 nm of straight segments of matching width were padded on the two ends to remove artifacts of finite length quantization.

In one embodiment, the term “a” or “one” or “an” refers to at least one. In one embodiment the phrase “two or more” may be of any denomination, which will suit a particular purpose. In one embodiment, “about” or “approximately” may comprise a deviance from the indicated term of +1%, or in some embodiments, −1%, or in some embodiments, 2.5%, or in some embodiments, ±5%, or in some embodiments, ±7.5%, or in some embodiments, ±10%, or in some embodiments, ±15%, or in some embodiments, ±20%, or in some embodiments, ±25.

1. A quantum computing device comprising:
a substrate;
a tapered nanowire (NW) disposed on said substrate;
a superconducting layer in quantum proximity with said tapered NW; and
a voltage source;
wherein said voltage source is connected to said tapered NW and configured to produce and manipulate at least one discrete superconducting region within said tapered NW.

2. The quantum computing device of claim 1 wherein Majorana Zero Modes (MZMs) are present at the boundaries of the said at least one discrete superconducting region.

3. The quantum computing device of claim 1 wherein said tapered NW comprises a semiconducting material.

4. The quantum computing device of claim 3 wherein said semiconducting material is a high spin-orbit coupling material.

5. The quantum computing device of claim 4 wherein said high spin-orbit coupling material is selected from Indium Arsenide (InAs) or Indium Antimonide (InSb).

6. The quantum computing device of claim 1 wherein said tapered NW is gate-defined.

7. The quantum computing device of claim 1 wherein said substrate is conductive.

8. The quantum computing device of claim 1 wherein said substrate is doped silicon.

9. The quantum computing device of claim 1 further comprising at least one insulating layer disposed in between said substrate and said tapered NW.

10. The quantum computing device of claim 1 wherein said superconducting layer comprises at least one superconducting metal.

11. The quantum computing device of claim 1 wherein said superconducting layer at least partially covers said tapered NW.

12. The quantum computing device of claim 1 further comprising at least one gate configured to control the electric potential within said tapered NW.

13. A crossed tapered NW device, said device comprising:
a substrate;
a first tapered NW and a second tapered NW, wherein the orientation of said first tapered NW is substantially orthogonal to the orientation of said second tapered NW;
at least one voltage source;
wherein said at least one voltage source is configured to produce and manipulate at least one discrete superconducting region within each of said first tapered NW and said second tapered NW; and
a magnet having an adjustable orientation for establishing a magnetic field at a selected orientation to change the length of said at least one superconducting region within each of said first tapered NW and said second tapered NW.

14. The crossed tapered NW device of claim 13 wherein said first tapered NW and said second tapered NW comprise a semiconducting high spin-orbit coupling material.

15. The crossed tapered NW device of claim 13 wherein said first tapered NW and said second tapered NW are gate-defined.

16. The crossed tapered NW device of claim 13 further comprising electrodes disposed at the ends of said first tapered NW and said second tapered NW and wherein said at least one voltage source is configured to apply a potential across each of said first tapered NW and said second tapered NW.

17. The crossed tapered NW device of claim 13 further comprising at least one gate configured to control the electric potential within said first tapered NW and said second tapered NW.

18. The crossed tapered NW device of claim 13 for use in a quantum computer.

19. A method of performing a quantum computing swap function, said method comprising: providing the crossed tapered NW device of claim 13;
adjusting the voltage of the first tapered NW and second tapered NW to zero volts with respect to the substrate;
adjusting the selected orientation of the magnetic field to increase the length of the superconducting region in the first tapered NW and decrease the length of the superconducting region in the second tapered NW;
increasing the voltage of the first tapered NW and second tapered NW to a first positive voltage with respect to the substrate;
increasing the voltage of the first tapered NW and second tapered NW to a second positive voltage with respect to the electrode, wherein the second positive voltage is greater than the first positive voltage;
adjusting the selected orientation of the magnetic field to increase the length of the superconducting region in the second tapered NW and decrease the length of the superconducting region in the first tapered NW; and
reducing the voltage of the first tapered NW and second tapered NW to zero volts with respect to the substrate.
